(19) United States
(12) Patent Application Publication
(10) Pub. No.: US 2015/0028868 A1
(43) Pub. Date: Jan. 29, 2015

(54) Local Coil for a Coil System of a Magnetic Resonance Imaging System

(71) Applicants: Yvonne Candidus, Tuchenbach (DE); Karsten Jahns, Buckenhof (DE); Helmut Kess, Erlangen (DE); Wolfgang Kraus, Furth (DE); Jörg Rothard, Litzendorf (DE)

(72) Inventors: Yvonne Candidus, Tuchenbach (DE); Karsten Jahns, Buckenhof (DE); Helmut Kess, Erlangen (DE); Wolfgang Kraus, Furth (DE); Jörg Rothard, Litzendorf (DE)

(21) Appl. No.: 14/339,099

(22) Filed: Jul. 23, 2014

(30) Foreign Application Priority Data
Jul. 23, 2013 (DE) DE 102013214330.3

(51) Int. Cl. G01R 33/34

(52) U.S. Cl. CPC G01R 33/3403; G01R 33/34092
USPC 324/307; 324/322

(57) ABSTRACT

A local coil for a coil system of a magnetic resonance imaging (MRI) system having a hot spot formed during operation of the magnetic resonance imaging system provides an MRI examination that is as pleasant as possible for a patient with a magnetic field strength that is as strong as possible. The local coil includes a heat dissipation plate arranged in a region of the hot spot.

This application claims the benefit of DE 10 2013 214 330.3, filed on Jul. 23, 2013, which is hereby incorporated by reference in its entirety.

### BACKGROUND

The present embodiments relate to a local coil for a coil system of a magnetic resonance imaging system having a hot spot forming during operation of the magnetic resonance imaging system.

Magnetic resonance imaging (MRI) may be used to produce section images of the human or animal body that allow organs and many pathological organ changes to be assessed. MRI is based on very strong magnetic fields, produced in an MRI system, and alternating magnetic fields in the radio frequency range, with which specific atomic nuclei (e.g., hydrogen nuclei/protons) in the body are excited by resonance. As a result of this, an electrical signal is induced in a receiver circuit.

MRI systems may have a transmitting unit that is provided for generating a substantially homogeneous radio-frequency field for exciting the nuclear spin. The associated transmitting coil may, for example, be configured as a “body coil” and may be fixedly incorporated in magnets and gradient coils. For spatial resolution of the signals, frequency and phase encoding is mapped in the pulse sequences transmitted via the transmitting coil. In a corresponding signal generation unit connected upstream of the transmitting coil, a corresponding module for producing frequency and phase variations is therefore provided. The module actuates a digitally controlled oscillator and produces the corresponding oscillations. The generated modulated signal is transferred to an amplifier (e.g., radio-frequency power amplifier (RFPA)). The RFPA amplifies the signal and transmits the signal to the transmitting coil.

In the clinical environment, 1.5 Tesla or 3 Tesla MRI systems may be used. However, the goal is a higher magnetic field strength of, for example, 7 Tesla, since the recorded MRI signal is significantly larger. With such higher field strengths (e.g., >3 T), instead of a body coil, a plurality of local coils is used for transmission in order to generate an excitation field that is as homogeneous as possible. These are antenna systems that are mounted in the direct vicinity on, under or in the body. Disturbing inhomogeneities caused by dielectric resonances are reduced in comparison with excitation using a whole body resonator. However, even in systems with field strengths of less than 3 Tesla, local coils are used as receiving or transmitting/receiving coils owing to the above advantages.

Specific points on the surface of such local coils may heat up. In other words, a hot spot forms during operation of the MRI system. Since the local coils are arranged directly in the region of the body, this heating may be experienced by patients as unpleasant.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a local coil that allows MRI examination with as high a magnetic field strength as possible, which is as pleasant as possible for the patient, is provided.

In one or more of the present embodiments, the local coil includes a heat dissipation plate arranged in a region of a hot spot.

In examinations using magnetic fields that are as strong as possible, local coils may not be dispensed with. Hot spots forming, for example, owing to a high distribution of magnetic fields and electrical fields of the whole body gradient coils that transfer corresponding generated heat to the patient may therefore be avoided. Avoiding the cause of the hot spots by restructuring the local coils is potentially expensive, complicated or not possible at all. The effect of the hot spots on the patients may thus be reduced in a more symptomatic approach. The generated heat is dissipated as quickly as possible and distributed over a surface. This is achievable by the local coil including a heat dissipation plate in the region of the hot spot.

Advantageously, the heat dissipation plate includes, for example, a non-magnetic and electrically insulating material. This is because magnetic and electrically conductive materials, which are brought into the magnetic resonance imaging system in the region of the strong magnetic field, are subject to a direct magnetic or Lorentz force. In extreme cases, the direct magnetic or Lorentz force may lead to the patient being put at risk. At the very least, however, image artifacts are produced (e.g., the quality of the MRI imaging deteriorates).

In an advantageous embodiment, the heat dissipation plate has a specific heat conductivity of more than 10 W per meter and Kelvin (W/mK). In a more advantageous embodiment, the heat dissipation plate has a specific heat conductivity of more than 100 W per meter and Kelvin. This provides quick dissipation and distribution of the heat away from the body of the patient.

Heat conductivities of more than 50 W/mK are reached, for example, by steel. Copper and aluminum also achieve very high heat conductivities. All these materials, however, may not be used in MRI systems due to corresponding magnetic and/or electrical properties. The heat dissipation plate therefore advantageously has a ceramic material. Ceramics are largely objects that are shaped from inorganic, finely granular raw materials with the addition of water at room temperature and subsequent drying (e.g., green bodies), and are fired in a subsequent firing process above 1000 K to form harder, more durable objects. Ceramics are non-magnetic and not electrically conductive, but have sufficient heat conductivity and are particularly suitable as heat dissipation plates in MRI systems.

The heat dissipation plate advantageously includes an aluminum nitride ceramic. Aluminum nitride ceramic may be sintered at temperatures of about 2100 K without pressure. Since AlN ceramic has a very good heat conductivity of 180 W/mK and at the same time is not electrically conductive and not magnetic, AIN ceramic is suitable as material for heat dissipation plates in MRI systems.

In a further embodiment, the surface area of the heat dissipation plate is greater than 5 cm². As a result, a sufficient distribution of the heat energy formed at the hot spot over a surface is provided.

A coil system for a magnetic resonance imaging system includes a described local coil. As a result, an MRI examination becomes particularly pleasant for the patient. At the same time, strong magnetic fields may be used for high-quality imaging.

A magnetic resonance imaging system includes such a coil system.

In one method for imaging using magnetic resonance imaging, such a magnetic resonance imaging system is used.

The advantages achieved with the present embodiments are that, owing to the introduction of heat dissipation plates into the local coils of an MRI system, very good heat dissipation is achieved, and thus, the examination is more pleasant for the patient. Under specific examination circumstances, the use of close-contact local coils is thus made possible. With the use of ceramic plates of aluminum nitride, a temperature reduction of about 10 K with excellent magnetic resonance compatibility is achieved. The heat dissipation plates may be adhesively bonded directly into the housings of the local coil, for example, using adhesive strips (e.g., double sided) or two-component adhesive.

### BRIEF DESCRIPTION OF THE DRAWINGS

FIG. 1 shows a cross-section through a local coil, and

FIG. 2 shows a magnetic resonance imaging system.

Same parts have the same reference signs throughout the figures.

### DETAILED DESCRIPTION

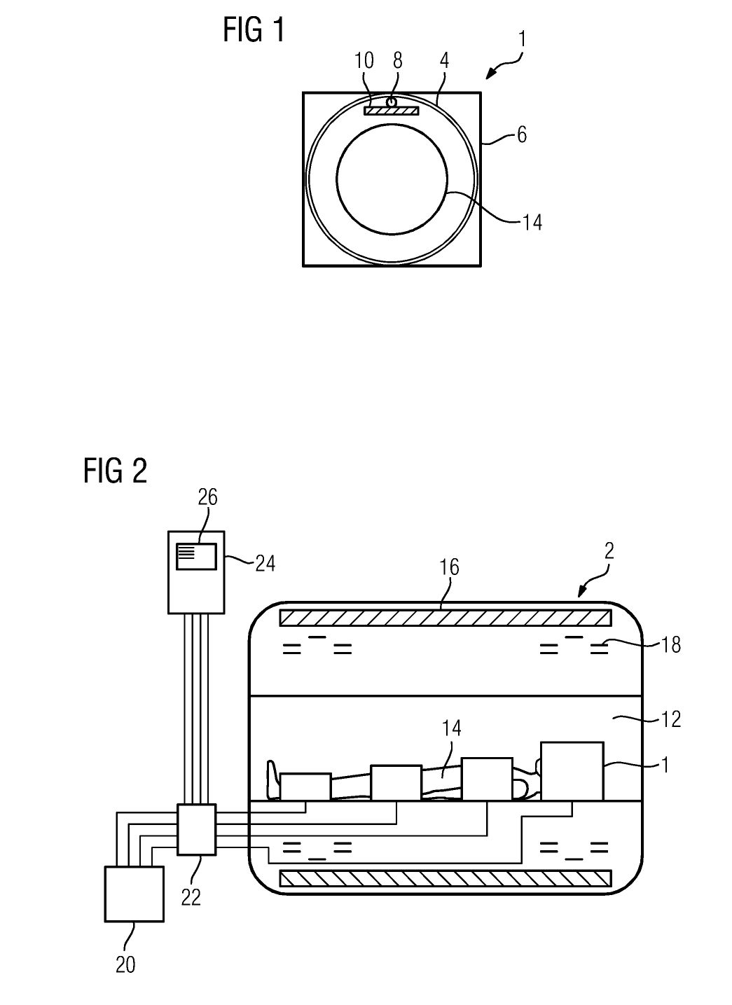

FIG. 1 illustrates a cross section through a local coil 1, as is used in a magnetic resonance imaging system 2. The magnetic resonance imaging system 2 will be explained in more detail in FIG. 2.

The local coil 1 has a coil 4 that is provided with connections (not illustrated in more detail) for supply with electrical signals. The coil 4 is arranged in a housing 6. During operation, the local coil 1 has a hot spot 8, at which a comparatively high heat develops. So as not to allow this heat to become unpleasant for a patient, a heat dissipation plate 10 is adhesively bonded into the housing 6 in a region of the hot spot 8. This may be done, for example, using adhesive strip or two-component adhesive.

The heat dissipation plate 10 is manufactured from aluminum nitride ceramic. The heat dissipation plate 10 thus has a specific heat conductivity of 180 W/mK and is electrically not conductive and not magnetic. The heat dissipation plate 10 has a surface area of more than 5 cm².

The magnetic resonance imaging system 2 is illustrated schematically in section in FIG. 2. The magnetic resonance imaging system 2 in FIG. 2 is configured for high field strengths of up to 7 Tesla, which is why local coils 1 are used to achieve a field that is as homogeneous as possible.

The patient 14 placed in a cylindrical tunnel 12 is surrounded by a strong magnet 16 that generates a magnetic field of, for example, 7 Tesla. Gradient coils 18 that may also surround the patient 14 in various axial regions and may overlay gradient fields are also provided. The gradient coils 18 are actuated by a transmitting unit 20 that is not, however, graphically illustrated for reasons of clarity. Four local coils 1 are arranged on the patient 14. The principle of the MRI measurement is briefly explained below.

The actual measurement is performed according to the principle of spin echo sequence. A “sequence” (e.g., “pulse sequence”) in this context is a combination of radio-frequency pulses emitted using the local coils 1 and magnetic gradient fields of specific frequency and strength that are produced in the gradient coils 18 and are switched on and off multiple times per second in a prespecified order. In the beginning, a radio-frequency pulse with the appropriate frequency (e.g., Larmor frequency) forms a 90° excitation pulse. With this, the magnetization is deflected through 90° transversely to the outer magnetic field. The magnetization begins to circulate the original axis (e.g., precession).

The radio-frequency signal produced in the process may be measured outside the body. The radio-frequency signal decreases exponentially because the proton spins go out of “sync” (e.g., “dephase”) and increasingly superpose destructively. The time after which 63% of the signal has disintegrated is the relaxation time (e.g., spin-spin relaxation). This time depends on the chemical environment of the hydrogen. The time differs for each tissue type. Tumor tissue may have, for example, a longer time than normal muscle tissue. A weighted measurement therefore displays the tumor as brighter than surroundings.

In order to be able to associate the measured signals with the individual volume elements (e.g., voxels), spatial encoding is generated with the linearly spatially dependent magnetic fields (e.g., gradient fields). For a specific particle, the Larmor frequency is dependent on the magnetic flux density (e.g., the stronger the field portion perpendicular to the direction of the particle spin, the higher the Larmor frequency). A gradient is present in the case of excitation and provides that only an individual layer of the body has the appropriate Larmor frequency. In other words, only the spins of this layer are deflected (e.g., layer selection gradient). A second gradient transverse to the first is switched on briefly after the excitation and brings about a controlled dephasing of the spin such that in each image row, the precession of the spins has a different phase orientation (e.g., phase encoding gradient). The third gradient is switched on during the measurement at right angles to the other two. The third gradient provides that the spins of each image column have a different precession rate (i.e., transmit a different Larmor frequency (readout gradient, frequency encoding gradient)). All three gradients together thus bring about an encoding of the signal in three spatial planes.

The signal is received in the magnetic resonance imaging system 2 in FIG. 2 likewise via the local coils 1. A switch 22 that conducts the output signal from the local coils 1 between the transmission pulses to an evaluation unit 24, where the output signal is decoded and displayed on a display unit 26 in the form of an image, is provided. The evaluation unit 24 may, for example, be a personal computer.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims can, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A local coil for a coil system of a magnetic resonance imaging system, the coil system having a hot spot formed during operation of the magnetic resonance imaging system, the local coil comprising:
a heat dissipation plate that is arranged in a region of the hot spot.

2. The local coil of claim 1, wherein the heat dissipation plate comprises a non-magnetic and electrically insulating material.

3. The local coil of claim 1, wherein the heat dissipation plate has a specific heat conductivity of more than 10 W/mK.

4. The local coil of claim 3, wherein the heat dissipation plate has a specific heat conductivity of more than 100 W/mK.

5. The local coil of claim 1, wherein the heat dissipation plate has a ceramic material.

6. The local coil of claim 5, wherein the heat dissipation plate comprises an aluminum nitride ceramic.

7. The local coil of claim 1, wherein a surface area of the heat dissipation plate is greater than 5 cm².

8. A coil system for a magnetic resonance imaging system, the coil system having a hot spot formed during operation of the magnetic resonance imaging system, the coil system comprising:
a local coil comprising a heat dissipation plate that is arranged in a region of the hot spot.

9. The coil system of claim 8, wherein the heat dissipation plate comprises a non-magnetic and electrically insulating material.

10. The coil system of claim 8, wherein the heat dissipation plate has a specific heat conductivity of more than 10 W/mK.

11. The coil system of claim 10, wherein the heat dissipation plate has a specific heat conductivity of more than 100 W/mK.

12. The coil system of claim 8, wherein the heat dissipation plate has a ceramic material.

13. The coil system of claim 12, wherein the heat dissipation plate comprises an aluminum nitride ceramic.

14. The coil system of claim 8, wherein a surface area of the heat dissipation plate is greater than 5 cm².

15. A magnetic resonance imaging system comprising:
a coil system having a hot spot formed during operation of the magnetic resonance imaging system, the coil system comprising:
a local coil comprising a heat dissipation plate that is arranged in a region of the hot spot.

16. The magnetic resonance imaging system of claim 15, wherein the heat dissipation plate comprises a non-magnetic and electrically insulating material.

17. The magnetic resonance imaging system of claim 15, wherein the heat dissipation plate has a specific heat conductivity of more than 10 W/mK.

18. The magnetic resonance imaging system of claim 17, wherein the heat dissipation plate has a specific heat conductivity of more than 100 W/mK.

19. The magnetic resonance imaging system of claim 15, wherein the heat dissipation plate has a ceramic material.

20. A method for imaging using magnetic resonance imaging, the method comprising:
arranging a local coil of a coil system of a magnetic resonance imaging system, such that a heat dissipation plate of the local coil is arranged in a region of a hot spot of the coil system formed during operation of the magnetic resonance imaging system.
